(19) United States
(12) Patent Application Publication
(10) Pub. No.: US 2026/0129928 A1
(43) Pub. Date: May 7, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Kai-Min CHIEN, New Taipei City (TW); Min-Chia LEE, Hsinchu City (TW); I-Hsiang MA, Hsinchu (TW); Kuo-Chin LIU, Ji-an Township (TW); Li-Wei YIN, Hsinchu City (TW); Yih-Ann LIN, Jhudong Township (TW); Ryan Chia-Jen CHEN, Hsinchu (TW)

(21) Appl. No.: 18/934,634

(22) Filed: Nov. 1, 2024

(51) Int. Cl. H01L 29/06; H01L 29/423; H01L 29/66; H01L 29/775; H01L 29/786

(52) U.S. Cl. CPC H10D 62/121; H10D 30/014; H10D 30/43; H10D 30/6735; H10D 30/6757; H10D 64/018

(57) ABSTRACT

Nanostructure channels of a nanostructure transistor are etched during a nanosheet release process for removing sacrificial nanostructure layers between the nanostructure channels. The etching of the nanostructure channels is controlled to increase the efficiency of the etching process such that impurities at central portions of the nanostructure channels are removed. In more detail, parameters such as temperature and/or pressure for etching are controlled to counter the high energy barriers and increase etchant adsorption. As a result, the uniformity in the material removal rates across the nanostructure channels during the etching process is improved so that the nanostructure channels are formed to have a substantially uniform surface profile. The techniques described herein may reduce channel resistance of the nanostructure transistor, which may increase the performance of the nanostructure transistor.

### BACKGROUND

As semiconductor device manufacturing advances and technology processing nodes decrease in size, transistors may become affected by short channel effects (SCEs) such as hot carrier degradation, barrier lowering, and quantum confinement, among other examples. In addition, as the gate length of a transistor is reduced for smaller technology nodes, source/drain (S/D) electron tunneling increases, which increases the off current for the transistor (the current that flows through the channel of the transistor when the transistor is in an off configuration). Silicon (Si)/silicon germanium (SiGe) nanostructure transistors such as nanowires, nanosheets, and gate-all-around (GAA) devices are potential candidates to overcome short channel effects at smaller technology nodes. Nanostructure transistors are efficient structures that may experience reduced SCEs and enhanced carrier mobility relative to other types of transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example implementation of a fin definition process described herein.

FIG. 2 is a diagram of an example dummy gate structure formation process described herein.

FIG. 3 is a diagram of an example implementation of a source/drain recess formation process described herein.

FIGS. 4A and 4B are diagrams of an example implementation of an inner spacer formation process described herein.

FIG. 5 is a diagram of an example implementation of a source/drain region formation process described herein.

FIG. 6 is a diagram of an example implementation of an interlayer dielectric formation process described herein.

FIGS. 7A-7C are diagrams of an example implementation of a nanosheet release process described herein.

FIGS. 8A and 8B are diagrams of an example implementation of a gate formation process described herein.

FIG. 9 is a diagram of an example of a semiconductor device described herein.

FIG. 10 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some nanostructure transistors (e.g., nanowire transistors, nanosheet transistors, gate-all-around (GAA) transistors, multi-bridge channel transistors, nanoribbon transistors, and/or other types of nanostructure transistors) include inner spacers between a source/drain region and a gate structure. The inner spacers may provide various process and/or performance benefits, such as electrical isolation between the source/drain region and the gate structure, and/or protections of the source/drain region from being etched during a replacement gate operation to replace sacrificial nanostructure layers with the gate structure.

However, the process of removing the sacrificial nanostructure layers between nanostructure channels to create vacancies for the gate structure can be challenging and may result in high levels of impurities in the nanostructure channels. For example, due to high energy barriers to overcome during etching, impurities may persist at certain portions of the nanostructure channels following the removal of the sacrificial nanostructure layers. Impurities in the nanostructure channels trap electrons, causing unwanted increases in channel resistance, thereby decreasing the performance of the nanostructure transistor.

In some implementations described herein, nanostructure channels of a nanostructure transistor are etched during a nanosheet release process for removing sacrificial nanostructure layers between the nanostructure channels. The etching of the nanostructure channels is controlled to increase the efficiency of the etching process such that impurities at central portions of the nanostructure channels are removed. In more detail, parameters such as temperature and/or pressure for etching are controlled to counter the high energy barriers and increase etchant adsorption. As a result, the uniformity in the material removal rates across the nanostructure channels during the etching process is improved so that the nanostructure channels are formed to have a substantially uniform surface profile. The techniques described herein may reduce channel resistance of the nanostructure transistor, which may increase the performance of the nanostructure transistor.

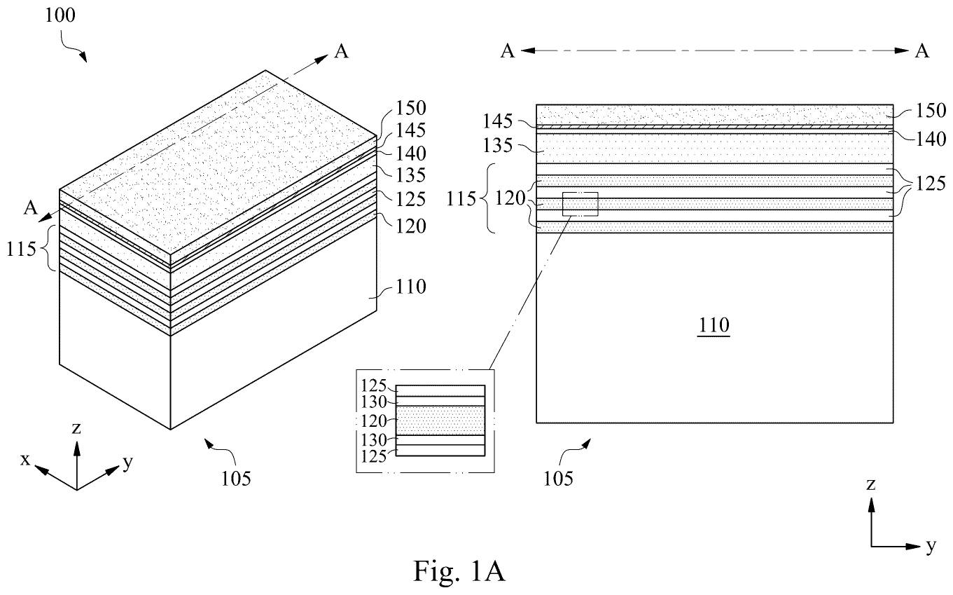

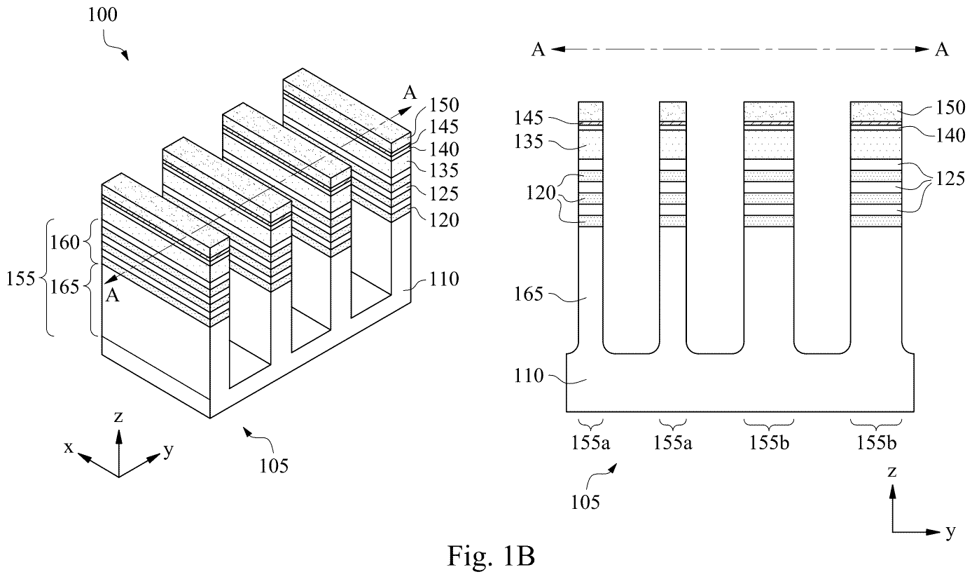

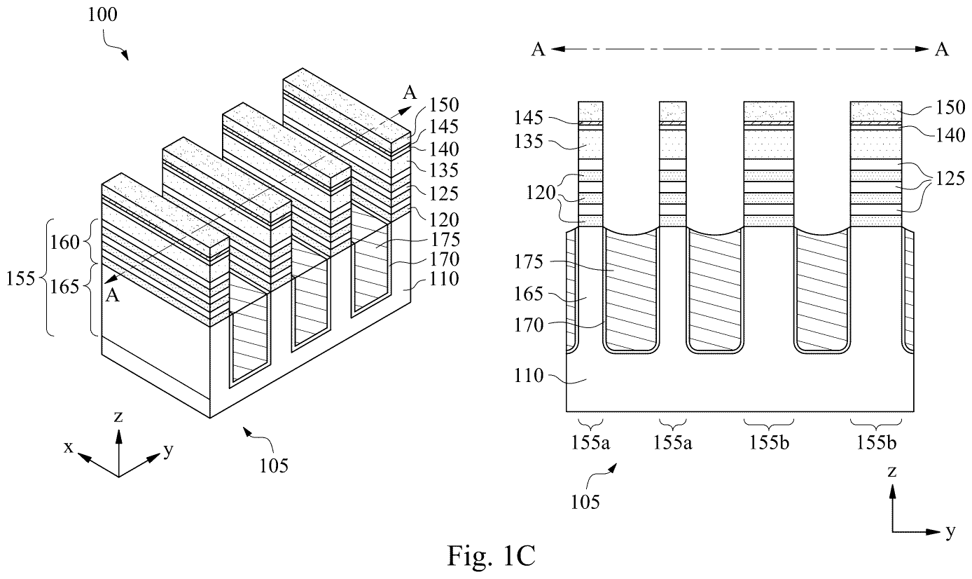

FIGS. 1A-1C are diagrams of an example implementation 100 of a fin definition process described herein. The example implementation 100 includes an example of forming fin structures and associated shallow trench isolation (STI) regions for a semiconductor device 105 described herein. The semiconductor device 105 may be manufactured to include one or more transistors. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The example implementation 100 includes an example of forming the fin structures and the associated STI regions for the transistors of the semiconductor device 105.

FIGS. 1A-1C each illustrate a perspective view of the semiconductor device 105 and a cross-sectional view along the line A-A in the perspective view. As shown in FIG. 1A, processing of the semiconductor device 105 is performed in connection with a semiconductor substrate 110. The semiconductor substrate 110 includes a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate.

A layer stack 115 is formed on the semiconductor substrate 110. The layer stack 115 may be referred to as a superlattice. The layer stack 115 includes a plurality of alternating layers that are arranged in a direction (e.g., the z-direction) that is approximately perpendicular to the semiconductor substrate 110. For example, the layer stack 115 includes vertically alternating layers of sacrificial nanostructure layers 120 and nanostructure channel layers 125 above the semiconductor substrate 110. The quantity of the sacrificial nanostructure layers 120 and the quantity of the nanostructure channel layers 125 illustrated in FIG. 1A are examples, and other quantities of the sacrificial nanostructure layers 120 and the nanostructure channel layers 125 are within the scope of the present disclosure.

The sacrificial nanostructure layers 120 enable a vertical distance to be defined between adjacent nanostructure channels that are formed from the nanostructure channel layers 125, and serve as placeholder layers for subsequently-formed gate structures of the transistors of the semiconductor device 105 that are formed around the nanostructure channels. The sacrificial nanostructure layers 120 include a first material composition, and the nanostructure channel layers 125 include a second material composition. In some implementations, the first material composition and the second material composition are the same material composition. In some implementations, the first material composition and the second material composition are different material compositions. As an example, the sacrificial nanostructure layers 120 may include silicon germanium (SiGe) and the nanostructure channel layers 125 may include silicon (Si). This enables the sacrificial nanostructure layers 120 and/or the nanostructure channel layers 125 to be selectively etched (e.g., enables the sacrificial nanostructure layers 120 and not the nanostructure channel layers 125 to be etched, enables the nanostructure channel layers 125 and not the sacrificial nanostructure layers 120 to be etched) depending on the type of etchant that is used.

One or more types of deposition tools may be used to deposit and/or grow the alternating layers of the layer stack 115 to include nanostructures (e.g., nanosheets) on the semiconductor substrate 110. For example, a deposition tool may be used to grow the sacrificial nanostructure layers 120 and/or the nanostructure channel layers 125 by epitaxial growth, which may include epitaxy techniques such as a molecular beam epitaxy (MBE), metalorganic chemical vapor deposition (MOCVD) process, and/or another suitable epitaxy technique. Additionally and/or alternatively, the sacrificial nanostructure layers 120 and/or the nanostructure channel layers 125 may be deposited by chemical vapor deposition (CVD), physical vapor deposition (PVD), atomic layer deposition (ALD), and/or another suitable deposition technique.

As shown in a close-up view in FIG. 1A of a portion of the layer stack 115, intermixing between two or more nanostructure layers in the layer stack 115 may occur. For example, intermixing may occur between a sacrificial nanostructure layer 120 and a vertically adjacent nanostructure channel layer 125. The intermixing may result in diffusion of silicon (Si) and/or germanium (Ge) between the sacrificial nanostructure layer 120 and the nanostructure channel layer 125. In some cases, the intermixing layers 130 are portions of the nanostructure channel layers 125 near the interface between the nanostructure channel layers 125 and the sacrificial nanostructure layers 120 that contain impurities in the form of diffused germanium (Ge) from the sacrificial nanostructure layers 120. Thus, the intermixing layers 130 may include regions of silicon (Si) in which germanium (Ge) has diffused.

One or more masking layers may be formed (e.g., using one or more deposition tools) on the layer stack 115. The masking layer(s) may include a hard mask (HM) layer 135, a capping layer 140, an oxide layer 145, and/or a nitride layer 150. Masking layer(s) may be used to perform a fin patterning operation to form fin structures in the semiconductor substrate 110.

As shown in FIG. 1B, the layer stack 115 and the semiconductor substrate 110 are etched to remove portions of the layer stack 115 and portions of the semiconductor substrate 110. This results in formation of fin structures 155 that extend above the semiconductor substrate 110. The fin structures 155 may extend in an x-direction in the semiconductor device 105 and may be arranged in a y-direction in the semiconductor device 105. A fin structure 155 includes a portion 160 of the layer stack 115 over and/or on a fin portion 165 above the semiconductor substrate 110. The fin structures 155 may be formed by patterning the one or more masking layers and etching the semiconductor substrate 110 based on a pattern formed in one or more of the masking layers. The one or more masking layers may be patterned using photolithography techniques, including double-patterning or multi-patterning techniques. An etch tool may be used to etch the semiconductor substrate 110 based on the pattern using a dry etch technique (e.g., reactive ion etching), a wet etch technique, and/or a combination thereof.

As further shown in FIG. 1B, some fin structures 155 may be formed to have different widths for different types of nanostructure transistors. As an example, a first subset of fin structures 155a may be formed for p-type nanostructure transistors (e.g., p-type metal oxide semiconductor (PMOS) nanostructure transistors), and a second subset of fin structures 155b may be formed for n-type nanostructure transistors (e.g., n-type metal oxide semiconductor (NMOS) nanostructure transistors). As another example, a first subset of fin structures 155a may be formed for nanostructure transistors that are configured to operate at lower voltages, and a second subset of fin structures 155b may be formed for nanostructure transistors that are configured to operate at higher voltages.

As shown in FIG. 1C, a liner 170 and STI regions 175 are formed between adjacent fin portions 165 of the fin structures 155. The liner 170 and the STI regions 175 may each include a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material.

A deposition tool may be used to conformally deposit the liner 170 (e.g., using ALD or another conformal deposition technique), and may deposit a dielectric layer (e.g., using CVD, PVD, a ALD, and/or another suitable deposition technique) on the liner 170 such that the dielectric layer fully fills in the spaces between the fin structures 155 and extends above the tops of the fin structures 155. A planarization tool may then be used to perform a planarization or polishing operation (e.g., a chemical mechanical planarization (CMP) operation) to planarize the dielectric layer such that the top surface of the dielectric layer is approximately co-planar with the top of the nitride layer 150. The nitride layer 150 functions as a CMP stop layer in the planarization operation. An etch tool may be used to then etch the dielectric layer to form the STI regions 175 such that the top surfaces of the STI region 175 are approximately co-planar with or below the bottom-most sacrificial nanostructure layer 120.

As indicated above, FIGS. 1A-1C are provided as an example. Other examples may differ from what is described with regard to FIGS. 1A-1C.

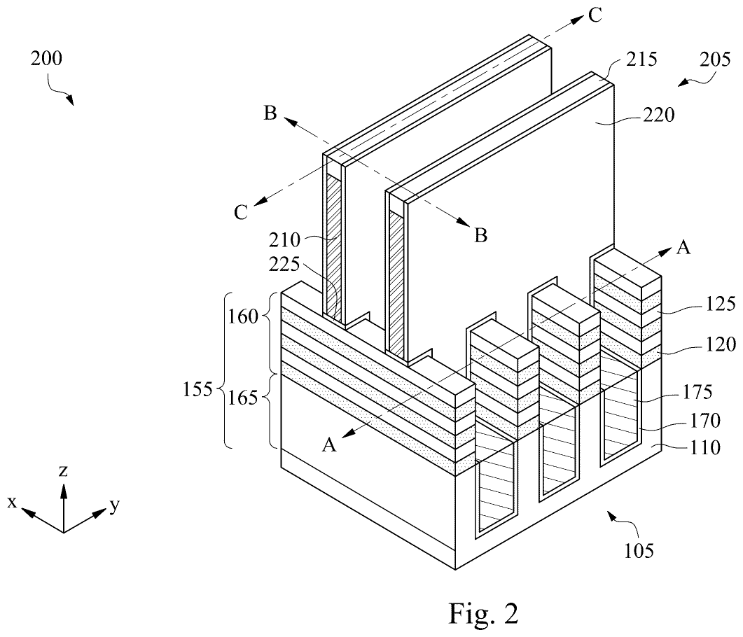

FIG. 2 is a diagram of an example implementation 200 of a dummy gate formation process described herein. The example implementation 200 includes an example of forming dummy gate structures 205 for nanostructure transistors of the semiconductor device 105. In some implementations, the operations described in connection with the example implementation 200 are performed after the processes described in connection with FIGS. 1A-1C.

FIG. 2 illustrates a perspective view of the semiconductor device 105 with the dummy gate structures 205 formed thereon. The dummy gate structures 205 (also referred to as dummy gate stacks or temporary gate structures) are formed over portions of the fin structures 155 and portions of the STI regions 175. The dummy gate structures 205 extend in the x-direction and are arranged in the y-direction such that the dummy gate structures 205 are approximately perpendicular to the fin structures 155. The dummy gate structures 205 are sacrificial structures that are to be replaced by replacement gate structures or replacement gate stacks at a subsequent processing stage for the semiconductor device 105. The dummy gate structures 205 may also be used to define source/drain (S/D) recesses in which source/drain regions of the nanostructure transistors are formed in the fin structures 155.

A dummy gate structure 205 may include a gate electrode layer 210, a hard mask layer 215 over and/or on the gate electrode layer 210, and spacer layers 220 on opposing sides of the gate electrode layer 210, and a gate dielectric layer 225 under the gate electrode layer 210. The gate electrode layer 210 includes polycrystalline silicon (polysilicon or PO) or another material. The hard mask layer 215 includes one or more layers such as an oxide layer (e.g., a pad oxide layer that may include silicon dioxide (SiO₂) or another material) and a nitride layer (e.g., a pad nitride layer that may include a silicon nitride such as Si₃N₄ or another material) formed over the oxide layer. The spacer layers 220 include a silicon oxycarbide (SiOC), a nitrogen free SiOC, or another suitable material. The gate dielectric layer 225 may include a silicon oxide (e.g., SiOₓ such as SiO₂), a silicon nitride (e.g., SiₓN_{y} such as Si₃N₄), a high dielectric constant (high-k) dielectric material (e.g., a dielectric material having a dielectric constant greater than approximately 3.9) and/or another suitable material.

The layers of the dummy gate structures 205 may be formed using various semiconductor processing techniques such depositing the layers of the dummy gate structures 205, patterning the layers of the dummy gate structures 205 to define the dummy gate structures 205, and/or other semiconductor processing techniques.

FIG. 2 further illustrates reference cross-sections that are used in subsequent figures described herein. Cross-section A-A is in an x-z plane (referred to as a y-cut) across the fin structures 155 in the source/drain areas of the semiconductor device 105. Cross-section B-B is in a y-z plane (referred to as an x-cut) perpendicular to the cross-section A-A, and is across the dummy gate structures 205 and along an underlying fin structure 155. Cross-section C-C is in the x-z plane parallel to the cross-section A-A and perpendicular to the cross-section B-B, and is along a dummy gate structure 205. Subsequent figures refer to these reference cross-sections for clarity. In some figures, some reference numbers of components or features illustrated therein may be omitted to avoid obscuring other components or features for ease of depicting the figures.

As indicated above, FIG. 2 is provided as an example. Other examples may differ from what is described with regard to FIG. 2.

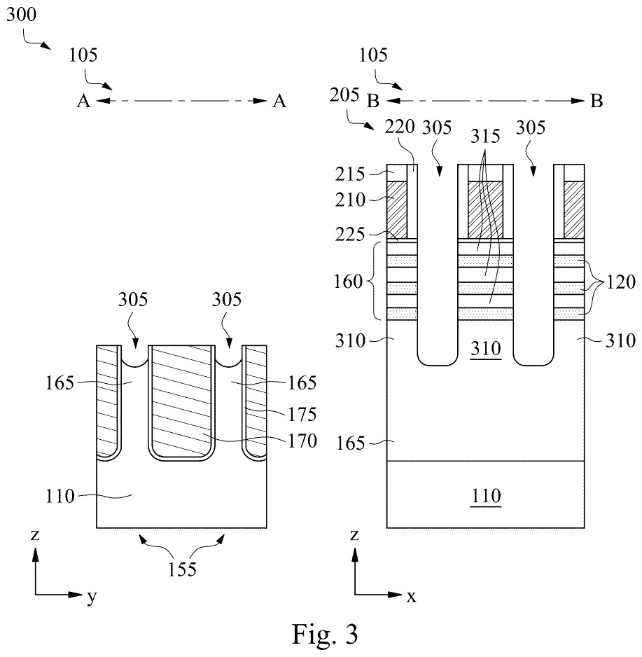

FIG. 3 is a diagram of an example implementation 300 of a source/drain recess formation process described herein. The example implementation 300 includes an example of forming source/drain recesses 305 for source/drain regions of nanostructure transistors of the semiconductor device 105. FIG. 3 is illustrated from a plurality of perspectives illustrated in FIG. 2, including the perspective of the cross-sectional plane A-A in FIG. 2 and the perspective of the cross-sectional plane B-B in FIG. 2. In some implementations, the operations described in connection with the example implementation 300 are performed after the processes described in connection with FIGS. 1A-2.

As shown in the cross-sectional plane A-A and cross-sectional plane B-B in FIG. 3, the source/drain recesses 305 are formed through portions 160 of a fin structure 155 in an etch operation. The source/drain recesses 305 are formed on opposing sides of a dummy gate structure 205. The etch operation may be performed using the etch tool and may be referred to a strained source/drain (SSD) etch operation. In some implementations, the etch operation includes the use of a plasma etch technique, a wet chemical etch technique, and/or another type of etch technique.

The source/drain recesses 305 also extend into a portion of the fin portion 165 of the fin structure 155. This results in formation of mesa regions 310 in the fin structure 155. The sidewalls of the portions of each source/drain recess 305 below the layer stack 115 correspond to sidewalls of mesa regions 310. A mesa region 310 (also referred to as pedestals) refers to a region of the fin portion 165 of the fin structure 155 on which nanostructure channels are defined from the nanostructure channel layers 125. The nanostructure channels 315 extend between adjacent source/drain recesses 305 and are located under the dummy gate structure 205 between the adjacent source/drain recesses 305.

The nanostructure channels 315 include silicon-based nanostructures (e.g., nanosheets or nanowires, among other examples) that function as the semiconductive channels of the nanostructure transistors of the semiconductor device 105. In some implementations, the nanostructure channels 315 may include silicon germanium (SiGe) or another silicon-based material. The nanostructure channels 315 are arranged in a direction (e.g., the z-direction) that is approximately perpendicular to the semiconductor substrate 110. In other words, the nanostructure channels 315 are vertically arranged or stacked above the semiconductor substrate 110.

As indicated above, FIG. 3 is provided as an example. Other examples may differ from what is described with regard to FIG. 3.

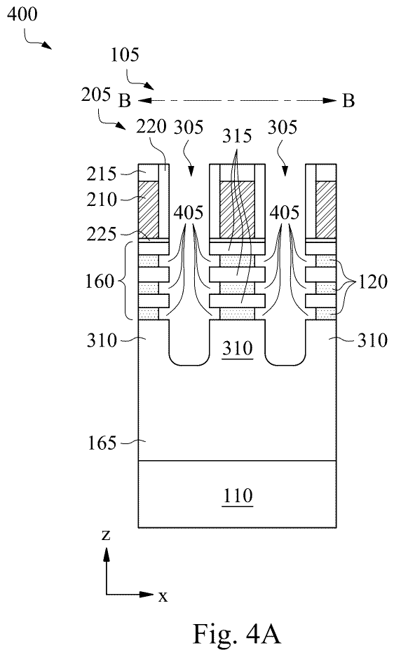

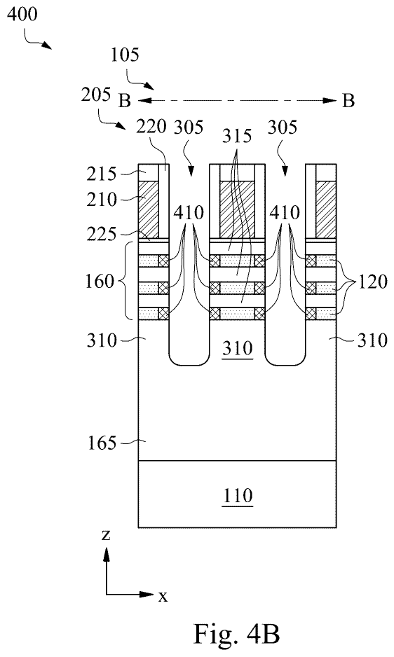

FIGS. 4A and 4B are diagrams of an example implementation 400 of an inner spacer formation process described herein. The example implementation 400 includes an example of forming inner spacers between ends of the nanostructure channels 315 that are exposed in the source/drain recesses 305. FIGS. 4A and 4B are each illustrated from the perspective of the cross-sectional plane B-B in FIG. 2. In some implementations, the operations described in connection with the example implementation 400 are performed after the processes described in connection with FIGS. 1A-3.

As shown in the cross-sectional plane B-B in FIG. 4A, the ends of the sacrificial nanostructure layers 120 that are exposed in the source/drain recesses 305 are laterally etched (e.g., in the x-direction that is approximately parallel to a length of the sacrificial nanostructure layers 120) in one or more first etch operations, thereby forming cavities 405 between the ends of the sacrificial nanostructure layers 120 that are exposed in the source/drain recesses 305. In particular, an etch tool may be used to laterally etch the ends of the sacrificial nanostructure layers 120 under the dummy gate structures 205 through the source/drain recesses 305 to form the cavities 405 between ends of the nanostructure channels 315.

In implementations where the sacrificial nanostructure layers 120 are silicon germanium (SiGe) and the nanostructure channels 315 are silicon (Si), the sacrificial nanostructure layers 120 are etched in the one or more first etch operations using a wet etchant such as a mixed solution including hydrogen peroxide (H₂O₂), acetic acid (CH₃COOH), and/or hydrogen fluoride (HF), followed by cleaning with water (H₂O). The mixed solution and the water may be provided into the source/drain recesses 305 to etch the sacrificial nanostructure layers 120 in the source/drain recesses 305. In some implementations, the etching by the mixed solution and cleaning by water is repeated for a plurality of cycles to form the cavities 405.

As shown in FIG. 4B, inner spacers 410 are formed in the cavities 405 between the ends of vertically adjacent nanostructure channels 315 in the source/drain recesses 305. The inner spacers 410 are included to reduce parasitic capacitance in the nanostructure transistors and to protect source/drain regions (that are subsequently formed in the source/drain recesses 305) from being etched in a nanosheet release operation to remove the sacrificial nanostructure layers 120 between the nanostructure channels 315. The inner spacers 410 include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material.

To form the inner spacers 410, a deposition tool may be used to deposit a layer of dielectric material in the cavities 405 and along the sidewalls and bottom surface of the source/drain recesses. A CVD technique, a PVD technique, and ALD technique, and/or another deposition technique may be used to deposit the layer of dielectric material. An etch tool is used to subsequently remove excess material of the layer of dielectric material from the source/drain recesses such that remaining portions correspond to the inner spacers 410 in the cavities 405. In some implementations, the etch operation may result in the surfaces of the inner spacers 410 facing the source/drain recesses 305 being curved or recessed. In some implementations, the surfaces of the inner spacers 410 facing the source/drain recesses 305 are approximately flat such that the surfaces of the inner spacers 410 and the surfaces of the ends of the nanostructure channels 315 are approximately even and flush.

As indicated above, FIGS. 4A and 4B provided as an example. Other examples may differ from what is described with regard to FIGS. 4A and 4B.

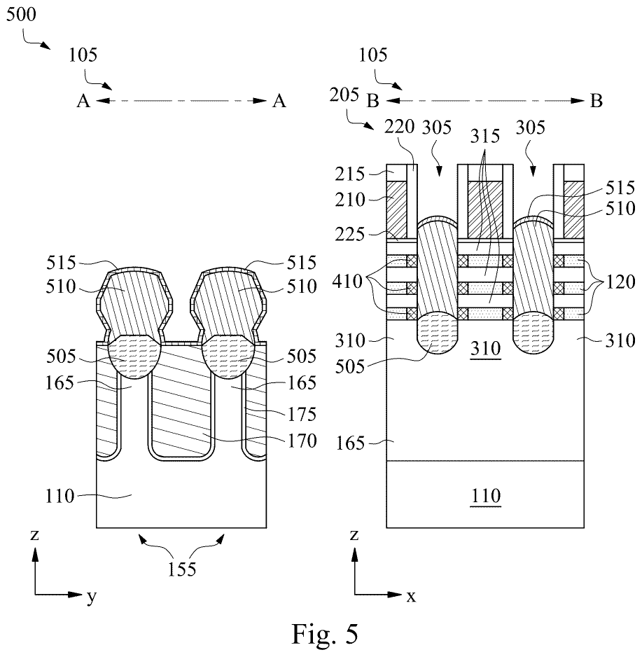

FIG. 5 is a diagram of an example implementation 500 of a source/drain region formation process described herein. The example implementation 500 includes an example of forming the source/drain regions of the nanostructure transistors of the semiconductor device 105. FIG. 5 is illustrated from a plurality of perspectives illustrated in FIG. 2, including the perspective of the cross-sectional plane A-A in FIG. 2 and the perspective of the cross-sectional plane B-B in FIG. 2. In some implementations, the operations described in connection with the example implementation 500 are performed after the processes described in connection with FIGS. 1A-4B.

As shown in the cross-sectional plane A-A and the cross-sectional plane B-B in FIG. 5, the source/drain recesses 305 are filled with one or more layers to form the source/drain regions in the source/drain recesses 305. For example, a deposition tool may be used to deposit a buffer region 505 at the bottom of the source/drain recess 305, and a deposition tool may deposit a source/drain region 510 on the buffer region 505 in the source/drain recess 305. In some implementations, a deposition tool is used to deposit a capping layer 515 on the source/drain regions 510 in the source/drain recess 305.

A buffer region 505 may include silicon (Si), silicon doped with boron (Si:B) or another dopant, and/or another material. A buffer region 505 may be included between a source/drain region 510 and the mesa regions 310 adjacent to the buffer region 505 to reduce, minimize, and/or prevent dopant migration and/or current leakage from the source/drain region 510 into the adjacent mesa region 310, which might otherwise cause short channel effects in the semiconductor device 105. Accordingly, the buffer region 505 may increase the performance of the semiconductor device 105 and/or increase yield of the semiconductor device 105.

“Source/drain region” may refer to a source or a drain, individually or collectively dependent upon the context. Source/drain regions 510 may be included on opposing sides of a dummy gate structure 205 such that the nanostructure channels 315 under the dummy gate structure 205 extend between, and are electrically coupled with, source/drain regions 510. The source/drain regions 510 each include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the semiconductor device 105 may include p-type metal-oxide semiconductor (PMOS) nanostructure transistors that include p-type source/drain regions 510, n-type metal-oxide semiconductor (NMOS) nanostructure transistors that include n-type source/drain regions 510, and/or other types of nanostructure transistors.

One or more layers of a source/drain region 510 may be epitaxially grown, deposited (e.g., using CVD, PVD, ALD), and/or may be formed using one or more other deposition techniques. For example, a deposition tool may epitaxially grow a first layer of a source/drain region 510 (referred to as an L1) over an associated buffer region 505 (which may be referred to as an L0), and may epitaxially grow a second layer of the source/drain region 510 (referred to as an L2, an L2-1, and/or an L2-2) over the first layer. The first layer may include a lightly doped silicon (e.g., doped with boron (B), phosphorous (P), and/or another dopant), and may be included as a shielding layer to reduce short channel effects in the semiconductor device 105 and to reduce dopant extrusion or migration into the nanostructure channels 315. The second layer may include a highly doped silicon or highly doped silicon germanium. The second layer may be included to provide a compressive stress in the source/drain regions 510 to reduce boron loss.

A capping layer 515 may include silicon, silicon germanium, doped silicon, doped silicon germanium, and/or another material. The capping layer 515 may be included to reduce dopant diffusion and to protect an underlying source/drain region 510 in semiconductor processing operations for the semiconductor device 105 prior to contact formation. Moreover, the capping layer 515 may contribute to metal-semiconductor (e.g., silicide) alloy formation.

As indicated above, FIG. 5 is provided as an example. Other examples may differ from what is described with regard to FIG. 5.

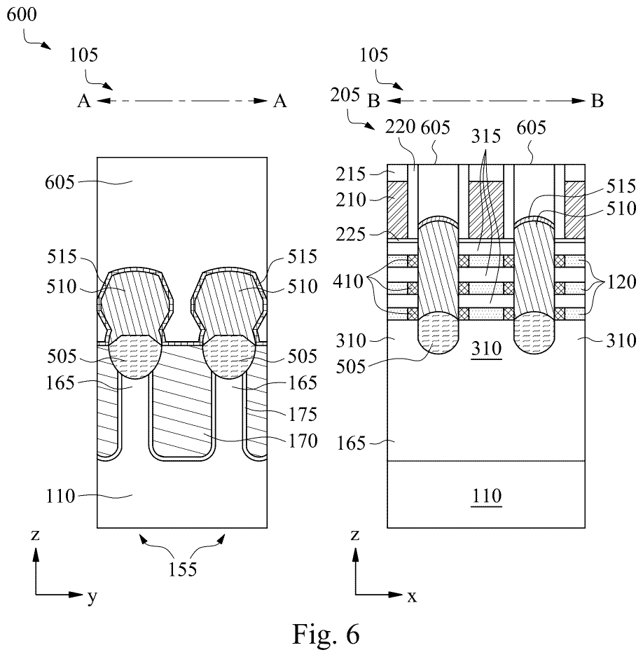

FIG. 6 is a diagram of an example implementation 600 of an interlayer dielectric (ILD) formation process described herein. FIG. 6 is illustrated from a plurality of perspectives illustrated in FIG. 2, including the perspective of the cross-sectional plane A-A in FIG. 2 and the perspective of the cross-sectional plane B-B in FIG. 2. In some implementations, the operations described in connection with the example implementation 600 are performed after the processes described in connection with FIGS. 1A-5.

As shown in the cross-sectional plane A-A and the cross-sectional plane B-B in FIG. 6, a dielectric layer 605 is formed over the source/drain regions 510. The dielectric layer 605 (which may be referred to as an ILD layer) fills in areas between the dummy gate structures 205. The dielectric layer 605 is formed to reduce the likelihood of and/or prevent damage to the source/drain regions 510 during a replacement gate process to replace the dummy gate structures 205. The dielectric layer 605 may be referred to as an ILD zero (ILD0) layer or another ILD layer.

In some implementations, a contact etch stop layer (CESL) is conformally deposited (e.g., by a deposition tool) over the source/drain regions 510 prior to formation of the dielectric layer 605. Alternatively, the capping layer 515 may be a CESL. The dielectric layer 605 is then formed on the CESL. The CESL may provide a mechanism to stop an etch process when forming contacts or vias for the source/drain regions 510. The CESL may be formed of a dielectric material having a different etch selectivity from adjacent layers or components. The CESL may include or may be a nitrogen containing material, a silicon containing material, and/or a carbon containing material. Furthermore, the CESL may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL may be deposited using a deposition process, such as ALD, CVD, or another deposition technique.

As indicated above, FIG. 6 is provided as an example. Other examples may differ from what is described with regard to FIG. 6.

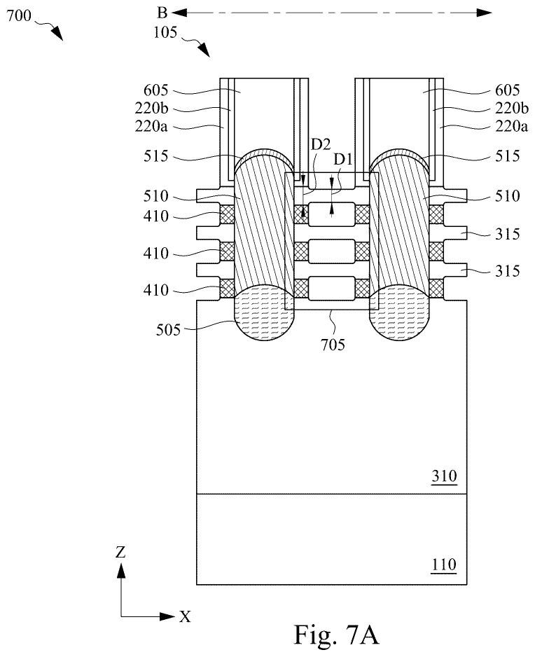

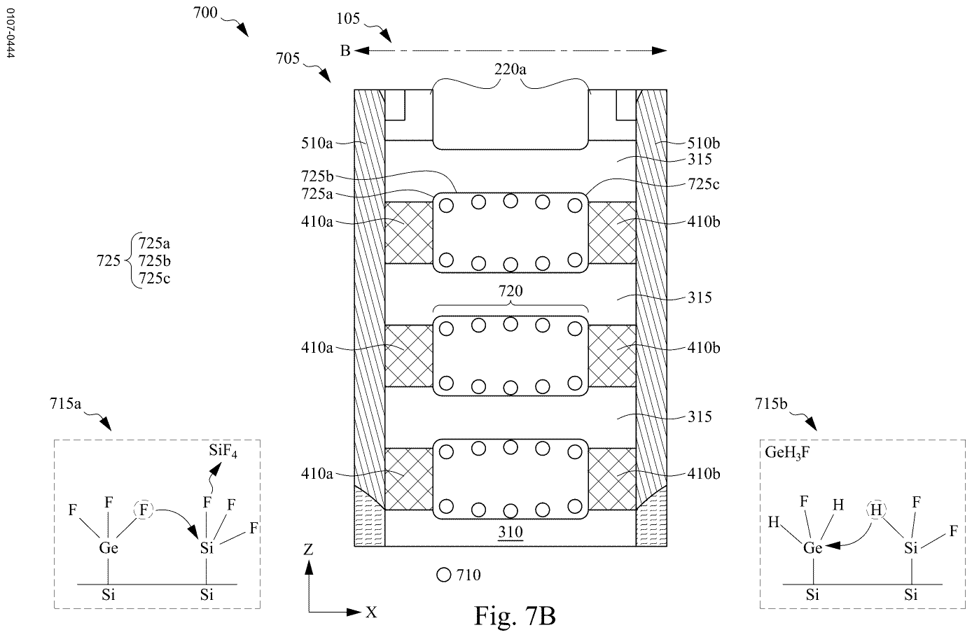

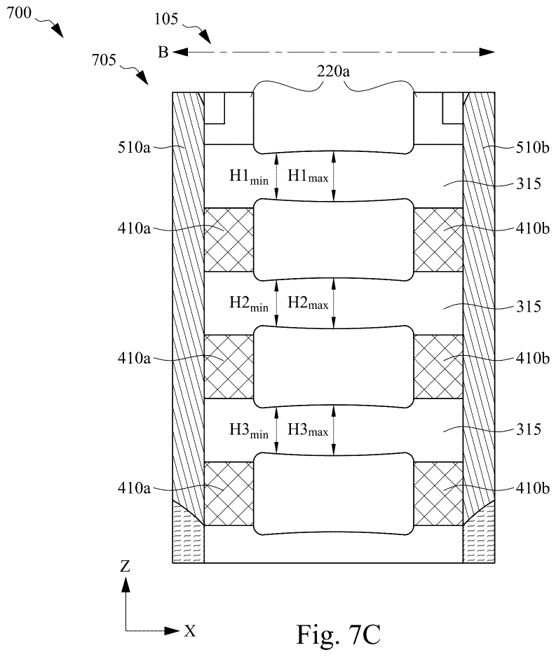

FIGS. 7A-7C are diagrams of an example implementation 700 of a nanosheet release process described herein. The nanosheet release process (e.g., a silicon germanium (SiGe) release process) is a process to remove the remaining portions of the sacrificial nanostructure layers 120 from between the nanostructure channels 315 of the semiconductor device 105. The nanosheet release process may be performed as part of a replacement gate (RPG) process that is performed to replace the dummy gate structures 205 with high-k/metal gate structures (e.g., the replacement gate structures) for the nanostructure transistors of the semiconductor device 105. FIGS. 7A-7C are each illustrated from the perspective of the cross-sectional plane B-B in FIG. 2. In some implementations, the operations described in connection with the example implementation 700 are performed after the operations described in connection with FIGS. 1A-6.

FIG. 7A illustrates an alternative configuration of the semiconductor device 105 from what is shown in FIG. 6 in that instead of spacer layers 220, FIG. 7A illustrates first spacer layers 220a and second spacer layers 220b on opposing sides of the dielectric layers 605. Like the spacer layers 220, the first spacer layers 220a and second spacer layers 220b include a silicon oxycarbide (SiOC), a nitrogen free SiOC, or another suitable material. The first spacer layers 220a and second spacer layers 220b may include the same or different materials from each other. In some implementations, the second spacer layers 220b are spacer liners and the first spacer layers 220a are bulk spacers.

A dummy gate removal operation may be performed prior to the nanosheet release process. The dummy gate removal operation includes removing the dummy gate structures 205 from the semiconductor device 105. The removal of the dummy gate structures 205 leaves behind openings (or recesses) between the dielectric layers 605, and provides access to the underlying sacrificial nanostructure layers 120 for the nanosheet removal process. The dummy gate structures 205 may be removed in one or more etch operations. Such etch operations may include a plasma etch technique, a wet chemical etch technique, and/or another type of etch technique.

The nanosheet release process may include performing an etch operation to laterally etch the sacrificial nanostructure layers 120 to remove the sacrificial nanostructure layers 120 from between vertically adjacent nanostructure channels 315. The etch operation further etches exposed portions of the vertically adjacent nanostructure channels 315 to create nanostructure channels 315 with a substantially uniform surface profile. As noted herein above and explained in more detail below, parameters such as temperature and/or pressure are controlled during the etch operation to counter high energy barriers and increase etchant adsorption at central portions of the nanostructure channels 315. The central portions of the nanostructure channels 315 are with respect to the x-direction (e.g., along the length of the nanostructure channels 315 between opposing first source/drain regions 510a and second source/drain regions 510b). As a result, the uniformity in the material removal rates across the nanostructure channels 315 (e.g., along the length of the nanostructure channels 315 between opposing sets of inner spacers 410 that are adjacent to the opposing first source/drain regions 510a and second source/drain regions 510b) during the etching process is increased so that the nanostructure channels 315 are formed to have the substantially uniform surface profile along the x-direction. Moreover, the increased material removal rate uniformity increases the likelihood that impurities (e.g., germanium (Ge) impurities) are fully removed from the top and bottom surfaces of the nanostructure channels 315, thereby increasing the performance of the nanostructure channels 315 by reducing the electrical resistance in the nanostructure channels 315.

As shown in FIG. 7A, the nanostructure channels 315 may each have a dimension D1 and a dimension D2. The dimension D1 corresponds to a z-direction (vertical) cross-sectional thickness at the centers of the nanostructure channels 315 (e.g., centers along the x-direction length of the nanostructure channels 315), and the dimension D2 corresponds to a z-direction (vertical) cross-sectional thickness at the ends (e.g., outer portions) of the nanostructure channels 315 (e.g., the ends along the x-direction length of the nanostructure channels 315 adjacent to the opposing source/drain regions 510a and 510b). Prior to the nanosheet release process, the z-direction thickness at the centers of the nanostructure channels 315 and the z-direction thickness at the ends of the nanostructure channels 315 are approximately equal thicknesses (e.g., dimension D1˜dimension D2). Following the nanosheet release process, the z-direction thickness at the centers of the nanostructure channels 315 is less than the z-direction thickness at the ends of the nanostructure channels 315 (e.g., dimension D1<dimension D2).

Referring to FIG. 7B, which illustrates the outlined portion 705 from FIG. 7A, the etch operation of the nanosheet release process includes providing an etchant 710 around the exposed portions of the sacrificial nanostructure layers 120 and the nanostructure channels 315. The etchant 710 is used to etch the sacrificial nanostructure layers 120 to remove the sacrificial nanostructure layers 120, as well as to trim or remove impurities (e.g., germanium (Ge) impurities that may correspond to the intermixing layers 130 that were formed between the sacrificial nanostructure layers 120 and the nanostructure channel layers 125) from the nanostructure channels 315. The semiconductor device 105 may be placed in a processing chamber of an etch tool, and the etchant 710 may be provided into the processing chamber as a mixture of process gasses that react with each other and/or with the material of the sacrificial nanostructure layers 120 and the nanostructure channels 315 to etch the sacrificial nanostructure layers 120 and the nanostructure channels 315.

The temperature and the pressure are controlled in the processing chamber during the etch operation to overcome high energy barriers (e.g., for removing material from the sacrificial nanostructure layers 120 and the nanostructure channels 315) that might otherwise result in difficultly in or inability to remove the germanium (Ge) impurities from center portions of the nanostructure channels 315. For example, in some implementations, the temperature in the processing chamber may be maintained in a range of approximately 20 degrees Celsius to approximately 60 degrees Celsius and the pressure in the processing chamber may be in a range of approximately 0.2 Torr to approximately 2 Torr. Although other ranges and values are the scope of the present disclosure, temperature within the above-noted range increases the adsorption of etchant gasses at central surfaces of the nanostructure channels 315. Pressure within the above-noted range increases etchant gas viscosity, making it more difficult for gas to diffuse away from central surfaces toward the ends of the nanostructure channels 315 that are in contact with the inner spacers 410. The increase in etchant gas viscosity increases the interaction between etchant gas molecules so that the etchant gasses are more easily adsorbed at the center portions of the nanostructure channels 315 than at the ends of the nanostructure channels 315 that are in contact with the inner spacers 410.

It is to be noted that etch temperatures that are too high can result in damage to the nanostructure channels 315, while etch temperatures that are too low can result in undesirably low etch rates of silicon germanium (SiGe) (which can be the material of the sacrificial nanostructure layers 120), thereby reducing productivity. Etch pressures that are too high can result in undesirably high etch rates of silicon germanium (SiGe), creating difficulties with controlling stability of the etch operation, while etch pressures that are too low can result in undesirably low etch rates of silicon germanium (SiGe), thereby reducing productivity.

The etchant 710 may include a gas-based etchant that includes a combination of a fluorine-based etchant (e.g., an F₂ gas) and a hydrofluoric acid etchant (e.g., an HF gas). Other gases, such as purge gasses, carrier gasses, and/or other reactant gasses may also be provided into the processing chamber during the etch operation. Such gasses may include an argon (Ar) gas, an ammonia (NH₃) gas, a chlorine trifluoride (CIF₃) gas, and/or a nitrogen (N₂) gas, among other examples. In some implementations, during the etch operation, the flow rate of the F₂ gas into the processing chamber may be in a range of approximately 20 standard cubic centimeters per minute (sccm) to approximately 250 sccm, and the flow rate of the HF gas into the processing chamber may be in a range of approximately 6 sccm to approximately 110 sccm. In addition a ratio of the fluorine-based etchant (e.g., the F₂ gas) to the hydrofluoric acid etchant (e.g., the HF gas) in the processing chamber may be in a range of approximately 10:1 to approximately 1:10 during the etch operation. However, other values and/or ranges for the gas flow rate and gas-to-gas ratio during the etch operation are within the scope of the present disclosure.

It is to be noted that flow rates of the fluorine-based etchant (e.g., the F₂ gas) that are too high cause undesirably high etch rates of silicon germanium (SiGe) (which can be the material of the sacrificial nanostructure layers 120), creating difficulties with controlling stability of the etch operation, and flow rates of the fluorine-based etchant that are too low cause undesirably low etch rates of silicon germanium (SiGe), thereby reducing productivity. Flow rates of the hydrofluoric acid etchant (e.g., the HF gas) that are too high cause selectivity issues, resulting in unwanted etching of dielectric layers, and flow rates of the hydrofluoric acid etchant that are too low result in non-uniform etching of silicon germanium (SiGe).

The etchant 710 may laterally etch the sacrificial nanostructure layers 120 in the etch operation starting at the outer edges of the sacrificial nanostructure layers 120 and etching toward the centers of the sacrificial nanostructure layers 120 until the sacrificial nanostructure layers 120 are fully removed (or substantially fully removed). The etchant 710 also etches exposed portions of the nanostructure channels 315 to remove impurities (e.g., germanium (Ge)) from the nanostructure channels 315 as described herein. Referring back to FIG. 1A, in some implementations, the etchant 710 removes the intermixing layers 130 if present, which may include at least some of the impurities. In some implementations, the etch operation is performed for a time duration of approximately 20 seconds to approximately 150 seconds to ensure that the sacrificial nanostructure layers 120, intermixing layers 130 and portions of the nanostructure channels 315 including unwanted impurities are fully removed without causing over-etching of the nanostructure channels 315. However, other ranges and values are within the scope of the present disclosure.

The etchant 710 may be used to etch the sacrificial nanostructure layers 120, the intermixing layers 130 and portions of the nanostructure channels 315 by removing silicon (Si) and/or germanium (Ge) from the sacrificial nanostructure layers 120, the intermixing layers 130 and portions of the nanostructure channels 315. Removal of silicon (Si) from the sacrificial nanostructure layers 120, the intermixing layers 130 and portions of the nanostructure channels 315 may result from a reaction between the fluorine-based etchant (e.g., the F₂ gas) in the etchant 710 and the silicon germanium (SiGe) in the sacrificial nanostructure layers 120, the intermixing layers 130 and portions of the nanostructure channels 315:

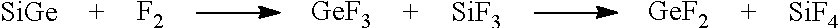

As shown in connection with reference number 715a in FIG. 7B, the fluorine-based etchant (e.g., the F₂ gas) in the etchant 710 may attach to the silicon (Si) and the germanium (Ge) in the sacrificial nanostructure layers 120, the intermixing layers 130 and portions of the nanostructure channels 315 to respectively form germanium trifluoride (GeF₃) and silicon trifluoride (SiF₃). A fluorine migration (F-migration) may occur where a fluorine (F) atom migrates from a germanium trifluoride molecule to a silicon trifluoride molecule, resulting in formation of germanium difluoride (GeF₂) and a silicon tetrafluoride (SiF₄) gas. The silicon tetrafluoride gas is removed from the semiconductor device 105, resulting in removal of silicon (Si) from the sacrificial nanostructure layers 120, the intermixing layers 130 and portions of the nanostructure channels 315. The fluorine (F) atom migration may occur at an energy in a range of approximately 0.3 electron-volts (eV) to approximately 0.35 eV. However, other values and/or ranges for the energy of the fluorine (F) atom migration are within the scope of the present disclosure. The fluorine (F) atom migration may be an exothermic process in which a change in enthalpy (AH) is included in a range of approximately-1.75 eV to approximately-2.0 eV. However, other values and/or ranges for the change in enthalpy are within the scope of the present disclosure.

The removal of germanium (Ge) from the sacrificial nanostructure layers 120, the intermixing layers 130 and portions of the nanostructure channels 315 may result from a reaction between a combination of the fluorine-based etchant (e.g., the F₂ gas) and the hydrofluoric acid etchant (e.g., the HF gas) in the etchant 710 and the silicon germanium (SiGe) in the sacrificial nanostructure layers 120, the intermixing layers 130 and portions of the nanostructure channels 315:

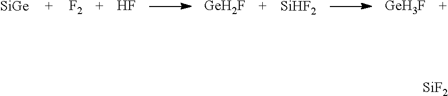

As shown in connection with reference number 715b in FIG. 7B, the fluorine (F) in the fluorine-based etchant (e.g., the F₂ gas) and/or in the hydrofluoric acid etchant (e.g., the HF gas) may attach to the silicon (Si) and the germanium (Ge) in the sacrificial nanostructure layers 120, the intermixing layers 130 and portions of the nanostructure channels 315. Moreover, the hydrogen in the hydrofluoric acid etchant of the etchant 710 may attach to the silicon (Si) and the germanium (Ge) in the sacrificial nanostructure layers 120, the intermixing layers 130 and portions of the nanostructure channels 315. The fluorine and the hydrogen react with the germanium to form germanium dihydrogen fluoride (GeH₂F) and silicon hydrogen difluoride (SiHF₂). A hydrogen migration (H-migration) may occur where a hydrogen (H) atom migrates from a silicon hydrogen difluoride molecule to a germanium dihydrogen fluoride molecule, resulting in formation of a germanium trihydrogen fluoride (GeH₃F) gas and silicon difluoride (SiF₂). The germanium trihydrogen fluoride gas is removed from the semiconductor device 105, resulting in removal of germanium (Ge) from the sacrificial nanostructure layers 120 and the intermixing layers 130. The hydrogen (H) atom migration may occur at an energy in a range of approximately 0.9 eV to approximately 1.0 eV. However, other values and/or ranges for the energy of the fluorine (F) atom migration are within the scope of the present disclosure. The hydrogen (H) atom migration may be an exothermic process in which a change in enthalpy (AH) is included in a range of approximately-0.75 eV to approximately-0.9 eV. However, other values and/or ranges for the change in enthalpy are within the scope of the present disclosure.

As shown in FIG. 7B, portions of the nanostructure channels 315 are etched during the etch operation to remove the sacrificial nanostructure layers 120. The removal of material from the tops and bottoms of the nanostructure channels 315 results in the nanostructure channels 315 having a curved or concave cross-sectional profile along the length of the nanostructure channels 315 (e.g., along the x-direction). In more detail, respective ones of the plurality of nanostructure channels 315 have an arc-shaped surface 720 along the x-direction direction between a first source/drain region 510a on a first side of the plurality of nanostructure channels 315 and a second source/drain region 510b on a second side of the plurality of nanostructure channels 315. If the techniques described herein for the etch operation of the nanosheet release process are not used, the resulting profile cross-sectional profile along the length of the nanostructure channels 315 (e.g., along the x-direction) might otherwise be wavy or W-shaped due to some impurities (e.g., germanium (Ge) impurities) remaining at the centers of the nanostructure channels 315.

A plurality of first inner spacers 410a are adjacent to the first source/drain region 510a, and a plurality of second inner spacers 410b are adjacent to the second source/drain region 510b. Respective arc-shaped surfaces 720 are between a first inner spacer 410a and a second inner spacer 410b opposing the first inner spacer 410a or between two opposing first spacer layers 220a. For example, the arc-shaped surface 720 of the uppermost nanostructure channel 315 in the z-direction includes opposite ends respectively contacting the two opposing first spacer layers 220a. The arc-shaped surfaces 720 of the nanostructure channels 315 below the uppermost nanostructure channel 315 in the z-direction include a first edge contacting a first inner spacer 410a and a second edge contacting a second inner spacer 410b.

Each arc-shaped surface 720 includes a first edge contacting a first inner spacer and a second edge contacting a second inner spacer. As can be seen in FIG. 7B, given ones of the arc-shaped surfaces 720 each include a first outer segment 725a, a center segment 725b and a second outer segment 725c (collectively “segments 725”) between a first inner spacer and a second inner spacer. The segments 725 are angled with respect to each other and are arranged in a U shape. The center segment 725b includes a substantially flat profile. Although two outer segments 725a and 725c and a center segment 725b are shown, other quantities of segments are within the scope of the present disclosure.

As shown in FIG. 7C, the nanostructure channels 315 may each have a dimension Hₘₐₓ and a dimension Hₘᵢₙ. The dimensions for the uppermost nanostructure channel 315 in the z-direction are referred to as H₁ₘₐₓ and H₁ₘᵢₙ. The dimensions for the center nanostructure channel 315 are referred to as H₂ₘₐₓ and H₂ₘᵢₙ. The dimensions for the lowermost nanostructure channel 315 in the z-direction are referred to as H₃ₘₐₓ and H₃ₘᵢₙ. The H₁ₘₐₓ, H₂ₘₐₓ and H₃ₘₐₓ dimensions are collectively referred to as Hₘₐₓ. The H₁ₘᵢₙ, H₂ₘᵢₙ and H₃ₘᵢₙ dimensions are collectively referred to as Hₘᵢₙ. The dimensions Hₘₐₓ correspond to maximum z-direction (vertical) cross-sectional thicknesses at central portions of the corresponding nanostructure channels 315 (e.g., central portions along the x-direction length of the nanostructure channels 315), and the dimensions Hₘᵢₙ correspond to minimum z-direction (vertical) cross-sectional thicknesses at central portions of the corresponding nanostructure channels 315 (e.g., central portions along the x-direction length of the nanostructure channels 315). The dimensions Hₘᵢₙ and the dimensions Hₘₐₓ each may be in the range of approximately 3 nanometers to approximately 8 nanometers.

In some implementations, following the nanosheet release process, a difference between Hₘₐₓ and Hₘᵢₙ for each nanostructure channel 315 (e.g., H₁ₘₐₓ−H₁ₘᵢₙ, H₂ₘₐₓ−H₂ₘᵢₙ, and H₃ₘₐₓ−H₃ₘᵢₙ) is less than or equal to approximately 0.5 nanometers and, in some cases, less than or equal to approximately 0.2 nanometers. In some implementations, following the nanosheet release process, a difference between maximum z-direction (vertical) thicknesses (Hₘₐₓ) for different nanostructure channels 315 (e.g., H₂ₘₐₓ−H₁ₘₐₓ, H₃ₘₐₓ−H₁ₘₐₓ, and H₃ₘₐₓ−H₂ₘₐₓ) is less than or equal to approximately 0.5 nanometers. In some implementations, following the nanosheet release process, a difference between minimum z-direction (vertical) thicknesses (Hₘᵢₙ) for different nanostructure channels 315 (e.g., H₂ₘᵢₙ−H₁ₘₙ, H₃ₘᵢₙ−H₁ₘᵢₙ, and H₃ₘᵢₙ−H₂ₘᵢₙ) is less than or equal to approximately 0.5 nanometers. However, other values and ranges for these differences are within the scope of the present disclosure.

As described above, the removal of silicon (Si) from the sacrificial nanostructure layers 120 and from the intermixing layers 130 involves the fluorine (F) migration between molecules formed from the silicon (Si) and the germanium (Ge) in the sacrificial nanostructure layers 120 and from the intermixing layers 130. The nanostructure channels 315, however, may not include germanium (Ge) and instead may include only silicon (Si). To achieve removal of silicon (Si) from the nanostructure channels 315 without the presence of germanium (Ge), the etch operation may be performed at a high temperature to provide sufficient energy to achieve the removal of silicon (Si) from the nanostructure channels 315 using the fluorine-based etchant (e.g., the F₂ gas) in the etchant 710.

For example, the temperature in the processing chamber may be elevated to a temperature that greater than 50 degrees Celsius and up to approximately 60 degrees Celsius, as described above. The etch operation may be performed while the temperature in the processing chamber is in this range to achieve the following reaction between the fluorine-based etchant (e.g., the F₂ gas) in the etchant 710 and the silicon (Si) in the nanostructure channels 315:

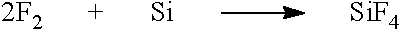

where the fluorine-based etchant (e.g., the F₂ gas) in the etchant 710 and the silicon (Si) in the nanostructure channels 315 react to form a silicon tetrafluoride (SiF₄) gas. The silicon tetrafluoride gas is removed from the semiconductor device 105, resulting in removal of silicon (Si) from the nanostructure channels 315. The reaction may occur at an energy in a range of approximately 1.1 electron-volts (eV) to approximately 1.2 eV. However, other values and/or ranges for the reaction are within the scope of the present disclosure.

As indicated above, FIGS. 7A-7C are provided as an example. Other examples may differ from what is described with regard to FIGS. 7A-7C.

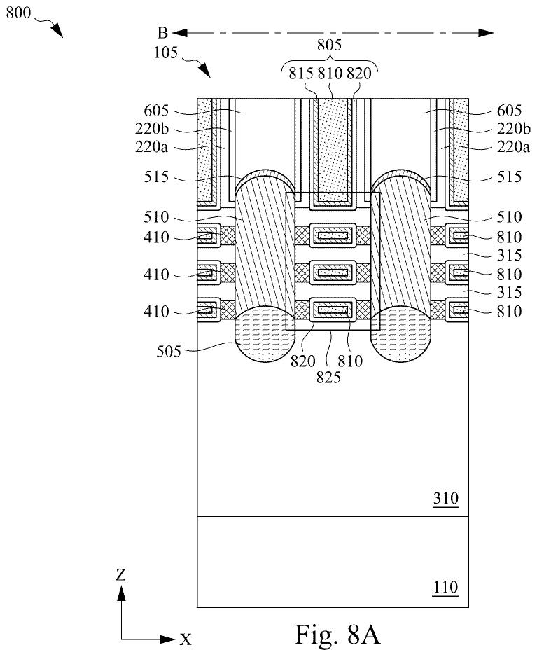

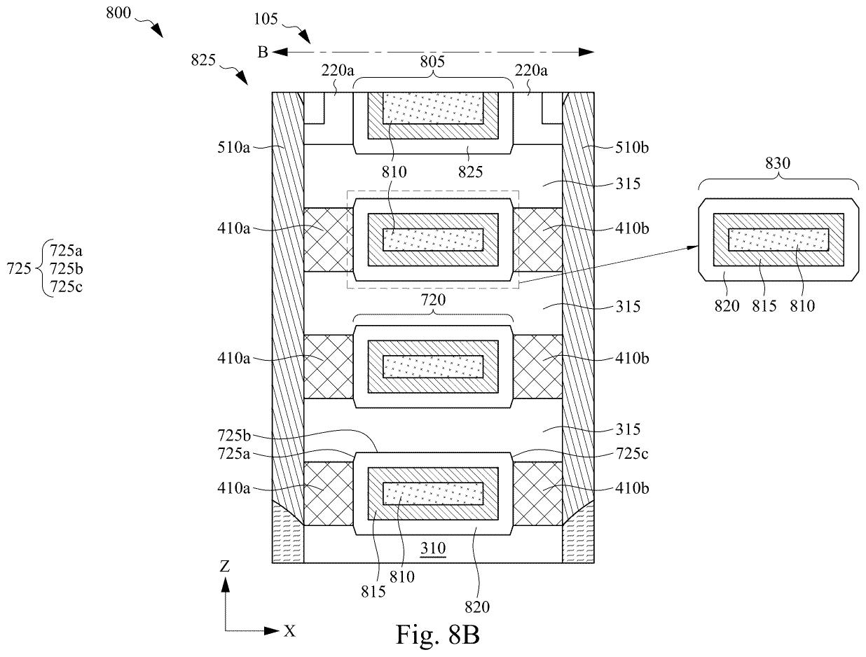

FIGS. 8A and 8B are diagrams of an example implementation 800 of a gate formation process described herein. The gate formation process may be performed as part of the replacement gate process that is performed to replace the dummy gate structures 205 with gate structures 805 (e.g., high-k/metal gate structures) for the nanostructure transistors of the semiconductor device 105. FIGS. 8A and 8B are each illustrated from the perspective of the cross-sectional plane B-B in FIG. 2. In some implementations, the operations described in connection with the example implementation 800 are performed after one or more of the operations described in connection with FIGS. 1A-7C.

As shown in FIG. 8A, a gate structure 805 may include a gate electrode layer 810, one or more work function metal layers 815, and a gate dielectric layer 820 (or the gate dielectric layer 820 may be considered separate from the gate structure 805). The gate dielectric layer 820 of a gate structure 805 may be formed around the nanostructure channels 315. In some implementations, the gate dielectric layer 820 is also formed on the mesa regions 310. A deposition tool may be used to deposit the gate dielectric layer 820 using a PVD technique, an ALD technique, a CVD technique, an oxidation technique, and/or another suitable deposition technique. In some implementations, the gate dielectric layer 820 is a high-k gate dielectric layer that includes one or more high-k materials (e.g., dielectric materials having a dielectric constant greater than silicon dioxide (SiO₂-dielectric constant of approximately 3.9). Examples include lanthanum oxide (LaₓO_{y} such as La₂O₃), hafnium oxide (HfOₓ such as HfO₂), zirconium oxide (ZrOₓ such as ZrO₂), and/or aluminum oxide (AlₓO_{y} such as Al₂O₃), among other examples. Additionally and/or alternatively, silicon dioxide (SiO₂) and/or another dielectric material may be used instead of a high-k dielectric material. In some implementations, the gate dielectric layer 820 may have a thickness that is included in a range of approximately 0.5 nanometers to approximately 3 nanometers. However, other values for the range are within the scope of the present disclosure.

The gate structure 805 includes a work function metal layer 815 formed on the gate dielectric layer 820 and a gate electrode layer 810 formed on the work function metal layer 815. A deposition tool may be used to deposit the work function metal layer 815 using a CVD technique, a PVD technique, an ALD technique, an electroplating technique, and/or another suitable deposition technique.

The work function metal layer 815 may be included for tuning the work function of the gate structure 805. In some implementations, the gate structure 805 is a p-type gate structure for a p-type metal-oxide-semiconductor (PMOS) nanostructure transistor, and the work function metal layer 815 is a p-type work function metal layer. In these implementations, the work function metal layer 815 may include one or more p-type metals, such as tungsten (W), cobalt (Co), titanium nitride (TiN), tungsten nitride (WN), and/or another metal having a work function that is greater than approximately 4.7 eV, among other examples, for tuning the work function of the gate structure 805 such that the work function is adjusted close to the valance band (Ex) of the material of the nanostructure channels 315. In some implementations, the gate structure 805 is an n-type gate structure for an n-type metal-oxide-semiconductor (NMOS) nanostructure transistor, and the work function metal layer 815 is an n-type work function metal layer. In these implementations, the work function metal layer 815 may include one or more n-type metals, such as titanium aluminum (TiAl) and/or titanium aluminum carbon (TiAlC), among other examples, for tuning the work function of the gate structure 805 such that the work function is close to the conduction band (Ec) of the material of the nanostructure channels 315.

The work function metal layer 815 may be formed such that the work function metal layer 815 wraps around the nanostructure channels 315 on one or more sides of the nanostructure channels 315. In some implementations, material of the work function metal layer 815 is deposited between vertically adjacent nanostructure channels 315. In some implementations, the work function metal layer 815 is merged between vertically adjacent nanostructure channels 315. Alternatively, the work function metal layer 815 is not merged and is instead spaced apart between vertically adjacent nanostructure channels 315 such that the work function metal layer 815 wrapping around each nanostructure channel 315 is spaced apart from the work function metal layers around vertically adjacent nanostructure channels 315.

The gate electrode layer 810 of the gate structure 805 may be formed over the work function metal layer 815. The gate electrode layer 810 may be formed such that the gate electrode layer 810 wraps around the nanostructure channels 315 on one or more sides of the nanostructure channels 315. Material of the gate electrode layer 810 may be deposited between vertically adjacent nanostructure channels 315. The gate electrode layer 810 includes one or more electrically conductive metal materials, such as ruthenium (Ru), tungsten (W), cobalt (Co), copper (Cu), and/or molybdenum (Mo), among other examples. A deposition tool may be used to deposit the gate electrode layer 810 using a CVD technique, a PVD technique, an ALD technique, an electroplating technique, and/or another suitable deposition technique. The gate electrode layer 810 may be deposited in one or more deposition operations. In some implementations, a seed layer is first deposited, and the gate electrode layer 810 is deposited on the seed layer. In some implementations, a planarization tool may be used to planarize the gate electrode layer 810 after the gate electrode layer 810 is deposited.

The curved or concave cross-sectional profile achieved for the nanostructure channels 315 using the nanosheet release techniques described in connection with FIGS. 7A-7C provides nanostructure channels 315 with a substantially uniform surface profile where impurities at central portions of the nanostructure channels 315 (e.g., germanium (Ge)) have been removed. As explained herein, parameters such as temperature and/or pressure are controlled during etching to counter the high energy barriers and increase etchant adsorption. As a result, the uniformity in material removal rates across the nanostructure channels 315 process is increased relative to other etch techniques. The implementations described herein may reduce channel resistance of the nanostructure transistor, which may increase the performance of the nanostructure transistor.

FIG. 8B illustrates a close-up view 825 (the location of which is indicated in FIG. 8A). As shown in FIG. 8B, sides of respective portions of the gate structure 805 adjacent to respective ones of the plurality of nanostructure channels 315 include a gate structure arc-shaped surface 830 which conforms to the arc-shaped surface 720 of an adjacent nanostructure channel 315. Similar to the arc-shaped surface 720, the gate structure arc-shaped shaped surface 830 extends along the length of the gate structure 805 in the x-direction between the first source/drain region 510a and the second source/drain region 510b. The gate structure arc-shaped surface 830 can be between a first inner spacer 410a and a second inner spacer 410b opposing the first inner spacer 410a or between two opposing first spacer layers 220a. For example, the gate structure arc-shaped surface 830 of the uppermost portion of the gate structure 805 in the z-direction includes opposite ends respectively contacting the two opposing first spacer layers 220a. The gate structure arc-shaped surfaces 830 of the portions of the gate structure 805 below the uppermost portion of the gate structure 805 in the z-direction include a first edge contacting a first inner spacer 410a and a second edge contacting a second inner spacer 410b. The gate dielectric layer 820 includes the gate structure arc-shaped surface 830. In order to conform to the concave profile of the arc-shaped surface 720, the gate structure arc-shaped surface 830 includes a convex profile.

As indicated above, FIGS. 8A and 8B are provided as an example. Other examples may differ from what is described with regard to FIGS. 8A and 8B.

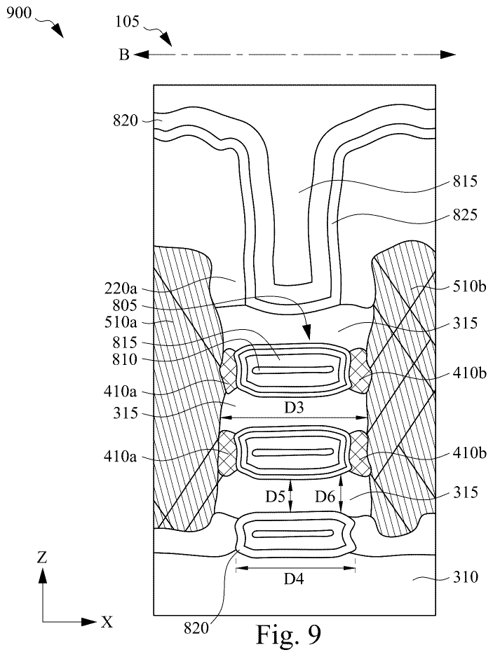

FIG. 9 is a diagram of an example implementation 900 of the semiconductor device 105 described herein, and is illustrated from the perspective of the cross-sectional plane B-B in FIG. 2. As shown in FIG. 9, the semiconductor device 105 may include a plurality of nanostructure channels 315 (arranged in the z-direction) in the semiconductor device 105. The nanostructure channels 315 extend in the x-direction between a first source/drain region 510a and a second source/drain region 510b. The semiconductor device 105 includes a gate structure 805 wrapping around the nanostructure channels 315 and a gate dielectric layer 820 between the nanostructure channels 315 and the gate structure 805. The gate structure 805 may include a work function metal layer 815 formed on the gate dielectric layer 820 and a gate electrode layer 810 formed on the work function metal layer 815. First spacer layers 220a are on sides of the gate structure 805.

Referring to FIG. 9, in some implementations, an x-direction length (dimension D3) of a nanostructure channel 315 (e.g., a channel length of the nanostructure channel 315) between a first source/drain region 510a and a second source/drain region 510b is included in a range of approximately 10 nanometers to approximately 30 nanometers. An x-direction length (dimension D4) of a gate structure 805 (e.g., the Lg of the gate structure) between a first inner spacer 410a and a second inner spacer 410b may be included in a range of approximately 10 nanometers to approximately 35 nanometers. However, other values and ranges are within the scope of the present disclosure.

As noted in FIG. 7C, the nanostructure channels 315 may each have a dimension Hₘₐₓ and a dimension Hₘᵢₙ. In FIG. 9, the dimensions D6 and D5 respectively correspond to the dimensions Hₘₐₓ and Hₘᵢₙ. The dimension D6 corresponds to a maximum z-direction (vertical) thickness at a central portion of a nanostructure channel 315 (e.g., central portion along the x-direction length (dimension D4) of the nanostructure channel 315), and the dimensions D5 corresponds to a minimum z-direction (vertical) thickness at a central portion of a nanostructure channel 315 (e.g., central portion along the x-direction length (dimension D4) of the nanostructure channel 315). The dimension D5 and the dimension D6 each may be in the range of approximately 3 nanometers to approximately 8 nanometers. As used herein, a “central portion” refers to a subset range of x-direction length (dimension D4) corresponding to the x-direction length of the center segment 725b of the arc-shaped surface 720. As noted herein, due to the pressure and temperature parameters used during the nanosheet release process, impurities (e.g., germanium (Ge)) are removed from the central portion, so that the center segment 725b of the arc-shaped surface 720 has a substantially flat (or slightly arc-shaped) profile. As a result, the difference between dimension D6 and dimension D5 is relatively small. For example, in some implementations, following the nanosheet release process, a difference between dimension D6 and dimension D5 for each nanostructure channel 315 (e.g., dimension D6-dimension D5) is less than or equal to approximately 0.5 nanometers and, in some cases, less than or equal to approximately 0.2 nanometers. In some implementations, the difference between dimension D6 and dimension D5 for relatively shorter values of x-direction length of a nanostructure channel 315 (dimension D3) may be smaller than the difference between dimension D6 and dimension D5 for relatively larger values of the x-direction length of a nanostructure channel 315 (dimension D3).

As indicated above, FIG. 9 is provided as an example. Other examples may differ from what is described with regard to FIG. 9.

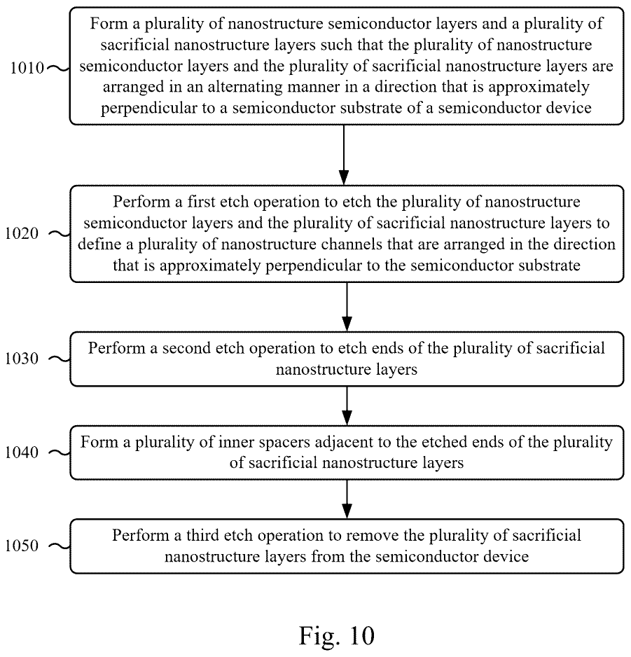

FIG. 10 is a flowchart of an example process 1000 associated with forming a semiconductor device. In some implementations, one or more process blocks of FIG. 10 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 10, process 1000 may include forming a plurality of nanostructure semiconductor layers and a plurality of sacrificial nanostructure layers such that the plurality of nanostructure semiconductor layers and the plurality of sacrificial nanostructure layers are arranged in an alternating manner in a direction that is approximately perpendicular to a semiconductor substrate of a semiconductor device (block 1010). For example, one or more semiconductor processing tools may be used to form a plurality of nanostructure semiconductor layers (e.g., nanostructure channel layers 125) and a plurality of sacrificial nanostructure layers (e.g., sacrificial nanostructure layers 120) such that the plurality of nanostructure semiconductor layers and the plurality of sacrificial nanostructure layers are arranged in an alternating manner in a direction (e.g., a z-direction) that is approximately perpendicular to a semiconductor substrate (e.g., a semiconductor substrate 110) of a semiconductor device (e.g., a semiconductor device 105), as described herein.

As further shown in FIG. 10, process 1000 may include performing a first etch operation to etch the plurality of nanostructure semiconductor layers and the plurality of sacrificial nanostructure layers to define a plurality of nanostructure channels that are arranged in the direction that is approximately perpendicular to the semiconductor substrate (block 1020). For example, one or more semiconductor processing tools may be used to perform a first etch operation to etch the plurality of nanostructure semiconductor layers and the plurality of sacrificial nanostructure layers to define a plurality of nanostructure channels (e.g., nanostructure channels 315) that are arranged in the direction that is approximately perpendicular to the semiconductor substrate, as described herein. In some implementations, the plurality of nanostructure channels and the plurality of sacrificial nanostructure layers are arranged in an alternating manner in the direction that is approximately perpendicular to the semiconductor substrate.

As further shown in FIG. 10, process 1000 may include performing a second etch operation to etch ends of the plurality of sacrificial nanostructure layers (block 1030). For example, one or more semiconductor processing tools may be used to perform a second etch operation to etch ends of the plurality of sacrificial nanostructure layers, as described herein.

As further shown in FIG. 10, process 1000 may include forming a plurality of inner spacers adjacent to the etched ends of the plurality of sacrificial nanostructure layers (block 1040). For example, one or more semiconductor processing tools may be used to form a plurality of inner spacers (e.g., first inner spacers 410a and second inner spacers 410b) adjacent to the etched ends of the plurality of sacrificial nanostructure layers, as described herein.

As further shown in FIG. 10, process 1000 may include performing a third etch operation to remove the plurality of sacrificial nanostructure layers from the semiconductor device (block 1050). For example, one or more semiconductor processing tools may be used to perform a third etch operation to remove the plurality of sacrificial nanostructure layers from the semiconductor device, as described herein. In some implementations, the third etch operation results in surfaces of respective nanostructure channels of the plurality of nanostructure channels having a curved concave shape that extends between a first inner spacer (e.g., an inner spacer 410a) of the plurality of inner spacers and a second inner spacer (e.g., an inner spacer 410b) of the plurality of inner spacers opposing the first inner spacer.

Process 1000 may include additional implementations, such as any single implementation or any combination of implementations described below and/or in connection with one or more other processes described elsewhere herein.

In a first implementation, performing the third etch operation includes performing the third etch operation at a temperature that is greater than or approximately equal to 20 degrees Celsius and less than or approximately equal to 60 degrees Celsius.

In a second implementation, alone or in combination with the first implementation, performing the third etch operation includes performing the third etch operation at a pressure that is greater than or approximately equal to 0.2 Torr and less than or approximately equal to 2 Torr.

In a third implementation, alone or in combination with one or more of the first and second implementations, performing the third etch operation includes performing the third etch operation using a fluorine-based etchant (e.g., as shown in connection with reference number 715a), where the fluorine-based etchant removes material from the plurality of nanostructure channels during the third etch operation.

In a fourth implementation, alone or in combination with one or more of the first through third implementations, performing the third etch operation includes performing the third etch operation using a hydrofluoric acid etchant (e.g., as shown in connection with reference number 715b), where the hydrofluoric acid etchant removes material from the plurality of sacrificial nanostructure layers during the second third operation.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, nanostructure channels of a nanostructure transistor are etched during a nanosheet release process for removing sacrificial nanostructure layers between the nanostructure channels. The etching of the nanostructure channels is controlled to increase the efficiency of the etching process such that impurities at central portions of the nanostructure channels are removed. In more detail, parameters such as temperature and/or pressure for etching are controlled to counter the high energy barriers and increase etchant adsorption. As a result, the uniformity in the material removal rates across the nanostructure channels during the etching process is improved so that the nanostructure channels are formed to have a substantially uniform surface profile. The techniques described herein may reduce channel resistance of the nanostructure transistor, which may increase the performance of the nanostructure transistor.

As described in greater detail above, some implementations described herein provide a semiconductor device. The semiconductor device includes a plurality of nanostructure channels arranged in a direction that is approximately perpendicular to a semiconductor substrate of the semiconductor device. The semiconductor device includes a gate structure wrapping around the plurality of nanostructure channels. The semiconductor device includes a first source/drain region adjacent to a first side of the gate structure. The semiconductor device includes a second source/drain region adjacent to a second side of the gate structure opposing the first side, where respective nanostructure channels of the plurality of nanostructure channels adjacent to the gate structure include an arc-shaped surface along a direction between the first source/drain region and the second source/drain region.

As described in greater detail above, some implementations described herein provide a semiconductor device. The semiconductor device includes a plurality of nanostructure channels arranged in a direction that is approximately perpendicular to a semiconductor substrate of the semiconductor device. The semiconductor device includes a gate structure wrapping around the plurality of nanostructure channels, a first source/drain region adjacent to a first side of the gate structure. The semiconductor device includes a second source/drain region adjacent to a second side of the gate structure opposing the first side, where sides of respective portions of the gate structure adjacent to respective nanostructure channels of the plurality of nanostructure channels include an arc-shaped surface along a direction between the first source/drain region and the second source/drain region.

As described in greater detail above, some implementations described herein provide a method. The method includes forming a plurality of nanostructure semiconductor layers and a plurality of sacrificial nanostructure layers such that the plurality of nanostructure semiconductor layers and the plurality of sacrificial nanostructure layers are arranged in an alternating manner in a direction that is approximately perpendicular to a semiconductor substrate of a semiconductor device. The method includes performing a first etch operation to etch the plurality of nanostructure semiconductor layers and the plurality of sacrificial nanostructure layers to define a plurality of nanostructure channels that are arranged in the direction that is approximately perpendicular to the semiconductor substrate, where the plurality of nanostructure channels and the plurality of sacrificial nanostructure layers are arranged in an alternating manner in the direction that is approximately perpendicular to the semiconductor substrate. The method includes performing a second etch operation to etch ends of the plurality of sacrificial nanostructure layers. The method includes forming a plurality of inner spacers adjacent to the etched ends of the plurality of sacrificial nanostructure layers. The method includes performing a third etch operation to remove the plurality of sacrificial nanostructure layers from the semiconductor device, where the third etch operation results in surfaces of respective nanostructure channels of the plurality of nanostructure channels having a curved concave shape that extends between a first inner spacer of the plurality of inner spacers and a second inner spacer of the plurality of inner spacers opposing the first inner spacer.

The terms “approximately” and “substantially” can indicate a value of a given quantity that varies within 5% of the value (e.g., +1%, +2%, +3%, +4%, +5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of nanostructure channels arranged in a direction that is approximately perpendicular to a semiconductor substrate of the semiconductor device;
a gate structure wrapping around the plurality of nanostructure channels;
a first source/drain region adjacent to a first side of the gate structure; and
a second source/drain region adjacent to a second side of the gate structure opposing the first side,
wherein respective nanostructure channels of the plurality of nanostructure channels adjacent to the gate structure comprise an arc-shaped surface along a direction between the first source/drain region and the second source/drain region.

2. The semiconductor device of claim 1, further comprising:
a plurality of first inner spacers adjacent to the first source/drain region; and
a plurality of second inner spacers adjacent to the second source/drain region,
wherein the arc-shaped surface is between a first inner spacer of the plurality of first inner spacers and a second inner spacer of the plurality of second inner spacers opposing the first inner spacer.

3. The semiconductor device of claim 2, wherein the arc-shaped surface comprises a first edge contacting the first inner spacer and a second edge contacting the second inner spacer.

4. The semiconductor device of claim 2, wherein:
the arc-shaped surface comprises a plurality of segments between the first inner spacer and the second inner spacer; and
the plurality of segments are angled with respect to each other.

5. The semiconductor device of claim 1, wherein:
the arc-shaped surface comprises at least two outer segments and a center segment between the at least two outer segments; and
the center segment comprises a substantially flat profile.

6. The semiconductor device of claim 5, wherein the at least two outer segments and the center segment are configured in a U shape.

7. The semiconductor device of claim 1, wherein the arc-shaped surface comprises a concave profile.

8. The semiconductor device of claim 1, wherein:
the respective nanostructure channels of the plurality of nanostructure channels comprise a first cross-sectional thickness at a central portion and a second cross-sectional thickness at outer portions adjacent to the first source/drain region and the second source/drain region; and
the first cross-sectional thickness is less than the second cross-sectional thickness.

9. The semiconductor device of claim 1, wherein:
the respective nanostructure channels of the plurality of nanostructure channels comprise a central portion having a first cross-sectional thickness and a second cross-sectional thickness; and
a difference between the first cross-sectional thickness and the second cross-sectional thickness is less than or equal to approximately 0.2 nanometers.

10. A semiconductor device, comprising:
a plurality of nanostructure channels arranged in a direction that is approximately perpendicular to a semiconductor substrate of the semiconductor device;
a gate structure wrapping around the plurality of nanostructure channels,
a first source/drain region adjacent to a first side of the gate structure; and
a second source/drain region adjacent to a second side of the gate structure opposing the first side,
wherein sides of respective portions of the gate structure adjacent to respective nanostructure channels of the plurality of nanostructure channels comprise an arc-shaped surface along a direction between the first source/drain region and the second source/drain region.

11. The semiconductor device of claim 10, further comprising:
a plurality of first inner spacers between the respective portions of the gate structure and the first source/drain region; and
a plurality of second inner spacers between the respective portions of the gate structure and the second source/drain region,
wherein the arc-shaped surface is between a first inner spacer of the plurality of first inner spacers and a second inner spacer of the plurality of second inner spacers opposing the first inner spacer.

12. The semiconductor device of claim 11, wherein the arc-shaped surface comprises a first edge contacting the first inner spacer and a second edge contacting the second inner spacer.

13. The semiconductor device of claim 10, wherein:
the respective portions of the gate structure comprise a gate dielectric layer and a metal layer on the gate dielectric layer; and
the gate dielectric layer comprises the arc-shaped surface.

14. The semiconductor device of claim 10, wherein the arc-shaped surface comprises a convex profile.

15. The semiconductor device of claim 14, wherein the arc-shaped surface corresponds to an arc-shaped surface of an adjacent nanostructure channel of the plurality of nanostructure channels comprising a concave profile.

16. A method, comprising:
forming a plurality of nanostructure semiconductor layers and a plurality of sacrificial nanostructure layers such that the plurality of nanostructure semiconductor layers and the plurality of sacrificial nanostructure layers are arranged in an alternating manner in a direction that is approximately perpendicular to a semiconductor substrate of a semiconductor device;
performing a first etch operation to etch the plurality of nanostructure semiconductor layers and the plurality of sacrificial nanostructure layers to define a plurality of nanostructure channels that are arranged in the direction that is approximately perpendicular to the semiconductor substrate,
wherein the plurality of nanostructure channels and the plurality of sacrificial nanostructure layers are arranged in an alternating manner in the direction that is approximately perpendicular to the semiconductor substrate;
performing a second etch operation to etch ends of the plurality of sacrificial nanostructure layers;
forming a plurality of inner spacers adjacent to the etched ends of the plurality of sacrificial nanostructure layers; and
performing a third etch operation to remove the plurality of sacrificial nanostructure layers from the semiconductor device,
wherein the third etch operation results in surfaces of respective nanostructure channels of the plurality of nanostructure channels having a curved concave shape that extends between a first inner spacer of the plurality of inner spacers and a second inner spacer of the plurality of inner spacers opposing the first inner spacer.

17. The method of claim 16, wherein performing the third etch operation comprises:
performing the third etch operation at a temperature that is greater than or approximately equal to 20 degrees Celsius and less than or approximately equal to 60 degrees Celsius.

18. The method of claim 16, wherein performing the third etch operation comprises:
performing the third etch operation at a pressure that is greater than or approximately equal to 0.2 Torr and less than or approximately equal to 2 Torr.

19. The method of claim 16, wherein performing the third etch operation comprises:
performing the third etch operation using a fluorine-based etchant,
wherein the fluorine-based etchant removes material from the plurality of nanostructure channels during the third etch operation.

20. The method of claim 16, wherein performing the third etch operation comprises:
performing the third etch operation using a hydrofluoric acid etchant,
wherein the hydrofluoric acid etchant removes material from the plurality of sacrificial nanostructure layers during the third etch operation.
